(19) United States
(12) Patent Application Publication
(10) Pub. No.: US 2014/0103507 A1
(43) Pub. Date: Apr. 17, 2014

(54) Optical Device Package And System

(71) Applicant: Avago Technologies General IP (Singapore) Pte. Ltd., (US)

(72) Inventors: Tee Khoon Guan, Penang (MY); Lum Chee Foo, Penang (MY)

(73) Assignee: Avago Technologies General IP (Singapore) Pte. Ltd., Singapore (SG)

(21) Appl. No.: 13/649,895

(22) Filed: Oct. 11, 2012

(51) Int. Cl. H01L 23/495

(52) U.S. Cl. 257/676; 257/E23.031

(57) ABSTRACT

Optical device packages and systems are disclosed. In one embodiment, a system may comprise first and second optical device packages. A respective first and second optical path length may be associated with the first and second optical device packages. The first and second optical path lengths may be adjusted differently. However, respective first and second sets of external dimensions of the first and second optical device packages may be the same or substantially the same. In one embodiment, one or more Quad Flat No Lead (QFN) packages may be employed.

### BACKGROUND

Optical devices, such as proximity sensors, encoders, opto-couplers, motion sensors, optical navigation sensors and the like are commonly used in electronic appliances, particularly portable electronic devices. An optical device may comprise an optical sensor, which may be assembled in a package or assembly. Light may be detected by the optical sensor either directly, or by way of reflection from an external object. The signal detected at the optical sensor may then processed further for various purposes, in accordance with the intended application.

In a package for an optical device, the optical sensor may often be encapsulated in a mold compound. Optical adjustment of these molded packages to meet optical requirements of various applications may be difficult. Furthermore, for applications employing optics of increasing complexity, it may be desirable to have configuration flexibility in choice of optical packages. This may reduce manufacturing complexity and cost.

### BRIEF DESCRIPTION OF THE DRAWINGS

Illustrative embodiments by way of examples, not by way of limitation, are illustrated in the drawings. Throughout the description and drawings, similar reference numbers may be used to identify similar elements. The drawings are for illustrative purpose to assist understanding and may not be drawn per actual scale.

FIGS. 1A and 1B show various views of a system of packaged optical devices;

FIGS. 2A and 2B show a system of user input devices.

### DETAILED DESCRIPTION

Novel device packages and systems are discussed in detail with reference to the figures. In one embodiment, a system may comprise first and second optical device packages. Respective first and second optical path length may be associated with the first and second optical device packages. The first and second optical path lengths may be adjusted differently. However, respective first and second sets of external dimensions of the first and second optical device packages may be the same, or substantially the same. In one embodiment, one or more Quad Flat No Lead (QFN) packages may be employed.

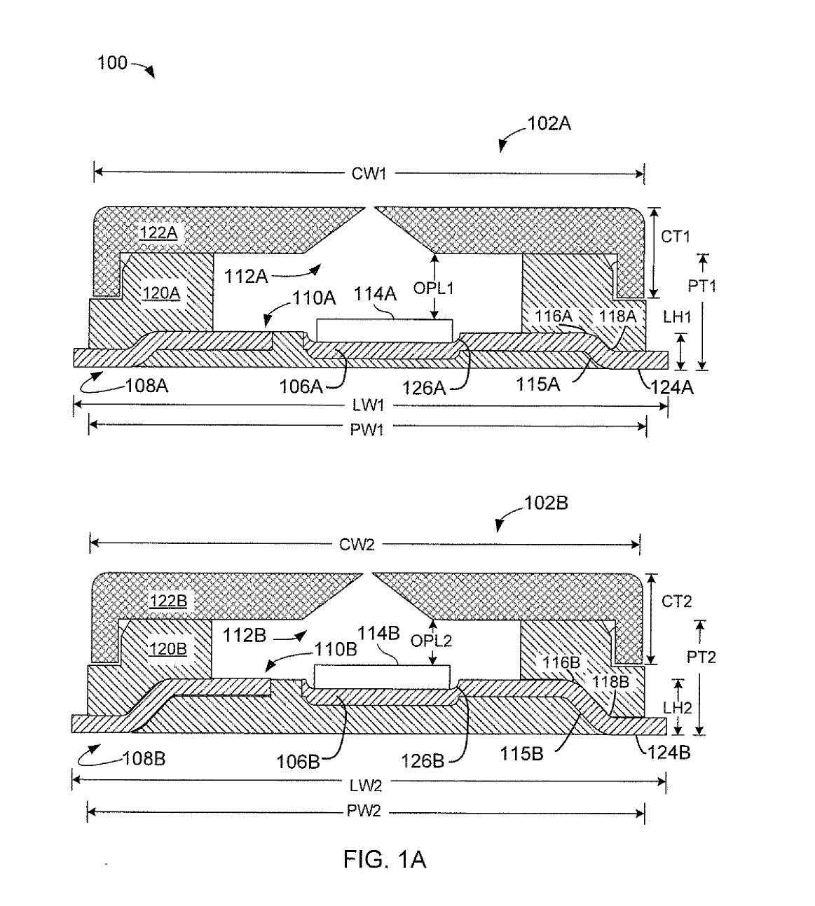

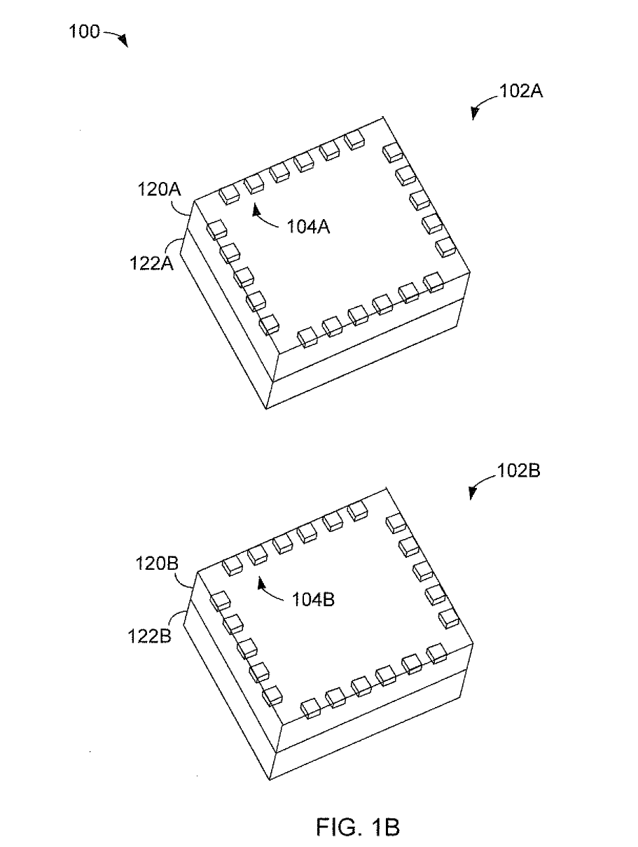

FIGS. 1A and 1B show various views of a system 100 comprising first and second packaged optical devices 102A, 102B. In FIG. 1A, the first and second packaged optical devices 102A, 102B are shown in cut away side view. In FIG. 1B, the first and second packaged optical devices 102A, 102B are shown in bottom view. As shown in the figures, the first and second packaged optical devices 102A, 102B may comprise Quad Flat No Lead (QFN) packages 102A, 102B.

The bottom view of FIG. 1B particularly shows extremities of respective first and second lead frames 104A, 104B extending from first and second package bodies 120A, 120B. As shown in the figures, respective first and second package covers 122A, 122B may be coupled with first and second package bodies 120A, 120B.

The first lead frame 104A of the first packaged optical device 102A may have a first die attach pad 106A, and may further have a first set of leads 108A. As particularly shown in FIG. 1A, each lead of the first set of leads may have a respective inner terminal portion 110A, which may be disposed adjacent to the first die attach pad 106A.

The first lead frame 104A may have a first height section 115A. The first height section 115A of the first lead frame 104A may have a first height dimension LH1.

A first optoelectronic die 114A may be mounted on the first die attach pad 106A. The first optoelectronic die 114A may be a first optical sensor 114A. One or more first wire bonds (not shown) may electrically couple the first optoelectronic die 114A to respective inner terminal portions 110A of members of the first set of leads 108A each having

A first optical component 112A may be coupled with first package cover 122A, which in turn may be coupled with the first package body 120A. The first optical component 112A may be arranged at a first optical path length OPL1 from the first optoelectronic die 114A. The first optical path length OPL1 may be disposed within the first packaged optical device 102A. The first height dimension LH1 of the lead frame 104A may be configured to provide for adjusting the first optical path length OPL1 to a desired first optical path length of the first packaged optical device 102A.

The first optical component 112A of the first packaged optical device 102A may comprise a first optical aperture 112A as shown in FIG. 1A. However, it should be understood that the first optical component 112A may be embodied in various different ways depending on desired optical function for a given application of the first packaged optical device 102A. For example, additionally or alternatively the first optical component 112A may comprise a lens (not shown).

Various applications may benefit from the arrangement of the first packaged optical device 102A shown in the figures. For example, as will be discussed in greater detail subsequently herein, the first packaged optical device 102A may comprise at least a portion of a first optical finger navigation device.

For the first packaged optical device 102A, each member of the first set of leads 108A may have a respective first pair of substantially opposing bends 116A, 118A. The first height section 115A of the first lead frame 104A and the first height dimension LH1 may extend between members of the first pair of substantially opposing bends 116A, 118A. The first pair of substantially opposing bends 116A, 118A may be configured to adjust the first height dimension LH1, so as to provide for adjusting the first optical path length OPL1 to the desired first optical path length OPL1 of the first packaged optical device 102A.

The first package body 120A of the first packaged optical device 102A may substantially encase the first height section 115A of the first lead frame 104A. The first package body 120A may be configured to interlock mechanically with the first height section 115A of the first lead frame 104A.

As already mentioned previously herein, the first packaged optical device 102A may comprise a first Quad Flat No Lead (QFN) package 102A. More generally, the first packaged optical device 102A may comprise a standardized package, such as a Joint Electron Devices Engineering Council (JEDEC) standardized package or an Electronic Industries Alliance (EIA) standardized package. Accordingly, it should be understood that the first Quad Flat No Lead (QFN) package 102A may comprise a first Quad Flat No Lead (QFN) lead frame 104A having the first die attach pad 106A, and further having the first set of leads 108A each having respective inner terminal portions 110A disposed adjacent to the first die attach pad 106A.

As already mentioned, each member of the set of leads may have the respective first pair of substantially opposing bends 116A, 118A. Further, the first die attach pad 106A may be integral with at least one member 124A of the first set of leads 108A, so as to provide a first integral lead 124A.

A first height section 115A of the first Quad Flat No Lead (QFN) lead frame 104A (or more generally, a first height section 115A of the first lead frame 104A) may extend between members of the first pair of substantially opposing bends 116A, 118A of the first integral lead 124A. As already mentioned, the first height section 115A may have a first height dimension LH1. The first height dimension LH1 of the first integral lead 124A may be configured to adjust positioning of the first die attach pad 106A.

Similar to what was just discussed with respect to the first packaged optical device 102A, the second packaged optical device 102B may comprise the second lead frame 104B. The second lead frame of the second packaged optical device 102B may have a second die attach pad 106B, and may further have a second set of leads 108B. As particularly shown in FIG. 1A, each lead of the second set of leads may have a respective inner terminal portion 110B, which may be disposed adjacent to the second die attach pad 106B.

The second lead frame 104B may have a second height section 115B. The second height section 115B of the second lead frame 104B may have a second height dimension LH2.

A second optoelectronic die 114B may be mounted on the second die attach pad 106B. The second optoelectronic die 114B may be a second optical sensor 114B. One or more second wire bonds (not shown) may electrically couple the second optoelectronic die 114B to respective inner terminal portions 110B of members of the second set of leads 108B.

A second optical component 112B may be coupled with second package cover 122B, which in turn may be coupled with the second package body 120B. The second optical component 112B may be arranged at a second optical path length OPL2 from the second optoelectronic die 114B. The second optical path length OPL2 may be disposed within the second packaged optical device 102B. [0001] The second height dimension LH2 of the lead frame may be configured to provide for adjusting the second optical path length OPL2 to a desired second optical path length of the second packaged optical device 102B.

The second optical component 112B of the second packaged optical device 102B may comprise a second optical aperture 112B as shown in FIG. 1A. However, just as with the first optical component 112A, it should be understood that the second optical component 112B may be embodied in various different ways depending on desired optical function and/or optical property for a given application of the second packaged optical device. For example, additionally or alternatively the second optical component 112B may comprise a lens (not shown). Moreover, it should be understood that in the system 100 of packaged optical devices 102A, 102B, the first and second optical components 112A, 112B may respectively comprise first and second optical apertures 112A, 112B or may comprise other optical components. Any of the first and second optical components may comprise an optical guide, an active optical component, a passive optical component, an optical emitter, an optical sensor, and/or an optical analyzer. Any of the first and second optical components may comprise an optical refractor, an optical diffractor, an optical isolator, an optical reflector, an optical polarizer, an optical filter, an optical resonator, an optical collimator, an optical fiber, and/or an optical crystal.

Just as with the first packaged optical device 102B, various applications may likewise benefit from the arrangement of the second packaged optical device 102B shown in the figures. The second packaged optical device 102B may comprise at least a portion of a second optical finger navigation device. Furthermore, for the system 100, it should be understood that the packaged optical devices 102A, 102B may comprise at least portions of optical finger navigation devices.

For the second packaged optical device 102B, each member of the second set of leads 108B may have a respective second pair of substantially opposing bends 116B, 118B. The second height section 115B of the second lead frame 104B and the second height dimension LH2 may extend between members of the second pair of substantially opposing bends 116B, 118B. The second pair of substantially opposing bends 116B, 118B may be configured to adjust the second height dimension LH1, so as to provide for adjusting the second optical path length OPL2 to the desired second optical path length of the second packaged optical device 102B.

The second package body 120B of the second packaged optical device 102B may substantially encase the second height section 115B of the second lead frame 104B. The second package body 120B may be configured to interlock mechanically with the second height section 115B of the second lead frame 104B.

In other words, for the system 100 of packaged optical devices 102A, 102B shown in the figures, first and second package bodies 120A, 120B may respectively encase substantially the first and second height sections 115A, 115B of the first and second lead frames 104A, 104B. The first and second package bodies 120A, 120B may be respectively configured to interlock mechanically with the first and second height sections 115A, 115B of the first and second lead frames 104A, 104B.

As already mentioned previously herein, the second packaged optical device 102B may comprise a second Quad Flat No Lead (QFN) package 102B. More generally, the second packaged optical device 102B may comprise a standardized package, such as a Joint Electron Devices Engineering Council (JEDEC) standardized package or an Electronic Industries Alliance (EIA) standardized package. Accordingly, it should be understood that the second Quad Flat No Lead (QFN) package 102B may comprise a second Quad Flat No Lead (QFN) lead frame 104B having the second die attach pad 106B, and further having the second set of leads 108B each having respective inner terminal portions 110B disposed adjacent to the second die attach pad 106B.

As already mentioned, each member of the set of leads may have the respective second pair of substantially opposing bends 116B, 118B. Further, the second die attach pad 106B may be integral with at least one member 124B of the second set of leads 108B, so as to provide a second integral lead 124B.

A second height section 115B of the second Quad Flat No Lead (QFN) lead frame 104B (or more generally, a second height section 115B of the second lead frame 104B) may extend between members of the second pair of substantially opposing bends 116B, 118B of the second integral lead 124B. As already mentioned, the second height section 115B may have a second height dimension LH2. The second height dimension LH2 of the second integral lead 124B may be configured to adjust positioning of the second die attach pad 106B.

Respective first and second lead frames 104A, 104B of the first and second packaged optical devices 102A, 102B, may be fabricated in various ways. In one embodiment, a stamping process may be used to form the first and second lead frames 104A, 104B from metal blanks. Stamping may provide some advantageous such as speed and efficiency in forming opposing bends 116A, 118A, 116B, 118B.

Stamping may likewise provide some advantageous such as speed and efficiency in forming respective first and second recessed regions 126A, 126B in the first and second die attach pads 106A, 106B. Respective first and second optoelectronic dies 114A, 114B (or more generally, first and second semiconductor dies 114A, 114B) may be secured to the first and second recessed regions 126A, 126B of the first and second die attach pads 106A, 106B. The first and second recessed regions 126A, 126B may provide some adhesion advantages, in securing respective first and second optoelectronic dies 114A, 114B (or more generally, first and second semiconductor dies 114A, 114B) to the first and second die attach pads 106A, 106B.

For the system 100 of packaged optical devices 102A, 102B shown in the figures, the first and second optoelectronic dies 114A, 114B may be respectively mounted on the first and second die attach pads 106A, 106B. Further the first and second optoelectronic dies 114A, 114B may be arranged so as to provide first and second optical path lengths OPL1, OPL2 extending respectively from the first and second optoelectronic dies 114A, 114B to the first and second optical components 112A, 112B. The first and second optical path lengths OPL1, OPL2 may be adjusted differently.

It should be understood that while first and second optical path lengths OPL1, OPL2 may shown in the figures as being adjusted differently, the system 100 of packaged optical devices is not limited to just two packaged optical devices 102A, 102B, and is not limited to just first and second optical path lengths OPL1, OPL2. Any number of packaged optical devices may be employed for the system 100. More particularly, any number of differently adjusted optical path lengths OPL1, OPL2, . . . , OPLn may be employed for the system 100. Furthermore, while some optical path lengths of some packaged optical devices of the system 100 may be adjusted differently, the system 100 may be used for a high volume of packaged optical devices, and some optical path lengths of some packaged optical devices of the system 100 may be adjusted to be substantially the same. The foregoing may provide for configuration flexibility in choice of optical path lengths for the system 100 of packaged optical devices.

In particular, the respective first and second height dimensions LH1, LH2 of the first and second lead frames 104A, 104B may be adjusted differently, and may be configured to provide for adjusting differently the first and second optical path lengths OPL1, OPL2. For example, as shown in the FIG. 1A, the first and second height dimensions LH1, LH2 may be configured so that the first optical path length OPL1 is substantially greater than the second optical path length OPL2.

Furthermore, as shown in FIG. 1A, the first height section 115A of the first lead frame 104A and the first height dimension LH1 may extend between members of the first pair of substantially opposing bends 116A, 118A. Similarly, the second height section 115B of the second lead frame 104B and the second height dimension LH2 may extend between members of the second pair of substantially opposing bends 116B, 118B. The first and second pairs of substantially opposing bends 116A, 118A, 116B, 118B are configured to provide for adjusting differently the first and second optical path lengths OPL1, OPL2.

Although first and second optical path lengths OPL1, OPL2 may be adjusted differently, for the system 100 respective first and second sets of external dimensions of the first and second optical device packages 102A, 102B may be the same, or substantially the same. This may provide for standardization of external dimensions for the system 100, which may be desirable for efficiency in handling and/or use of the optical device packages 102A, 102B.

For example, the first lead frame 104A may have a first lead frame width dimension LW1 extending between outer extremities of opposing members of the first set of leads 108A. Similarly, the second lead frame 104B may have a second lead frame width dimension LW2 extending between outer extremities of opposing members of the second set of leads 108B. The first and second lead frame width dimensions LW1, LW2 may be substantially equal so as to provide a standardized lead frame width dimension of the system 100 of packaged optical devices 102A, 102B, while respective first and second optical path lengths OPL1, OPL2 may be adjusted differently.

As another example, first and second package bodies 120A, 120B may have respective first and second package width dimensions PW1, PW2 extending between respective opposing lateral sides of the first and second package bodies 120A, 120B. The first and second package width dimensions PW1, PW2 may be substantially equal so as to provide a standardized package width dimension of the system 100 of packaged optical devices 102A, 102B, while respective first and second optical path lengths OPL1, OPL2 may be adjusted differently.

As another example, first and second package covers 122A, 122B may have respective first and second cover width dimensions CW1, CW2 extending between respective opposing lateral sides of the first and second package covers 122A, 122B. The first and second cover width dimensions CW1, CW2 may be substantially equal so as to provide a standardized cover width dimension of the system 100 of packaged optical devices 102A, 102B, while respective first and second optical path lengths OPL1, OPL2 may be adjusted differently.

Furthermore, various different optical components having various different optical functionality and/or optical property may be coupled to package covers 122A, 122B. Standardization of cover width dimensions for the system 100 may facilitate interchangeability of the package covers, which in turn may facilitate interchangeability of optical components having various different optical functionality and/or optical property. In applications employing optics of increasing complexity, it may be desirable to have configuration flexibility in choice of optical path lengths OPL1, OPL2 and/or in choice of interchanging optical components for the system 100 of packaged optical devices 102A, 102B.

As yet another example of external dimensions of packaged optical devices of system 100, the first and second package bodies 120A, 120B may have respective first and second package thickness dimensions PT1, PT2. The first and second package thickness dimensions PT1, PT2 may be substantially equal so as to provide a standardized package thickness dimension of the system 100 of packaged optical devices 102A, 102B, while the first and second optical path lengths OPL1, OPL2 may be adjusted differently.

As shown in FIG. 1A, the first optical path length OPL1 may extend from the first optoelectronic die 114A to the first optical component 112A. The first optical path length OPL1 may be oriented substantially parallel to the first package thickness dimension PT1 of the first package body 120A. Similarly, the second optical path length OPL2 may extend from the second optoelectronic die 114B to the second optical component 112B. The second optical path length OPL2 may be oriented substantially parallel to the second package thickness dimension PT2 of the second package body 120B.

As yet another example of external dimensions of packaged optical devices of system 100, the first and second package covers 122A, 122B may have respective first and second cover thickness dimensions CT1, CT2. The first and second cover thickness dimensions CT1, CT2 may be substantially equal so as to provide a standardized cover thickness dimension of the system 100 of packaged optical devices 102A, 102B, while the first and second optical path lengths OPL1, OPL2 may be adjusted differently.

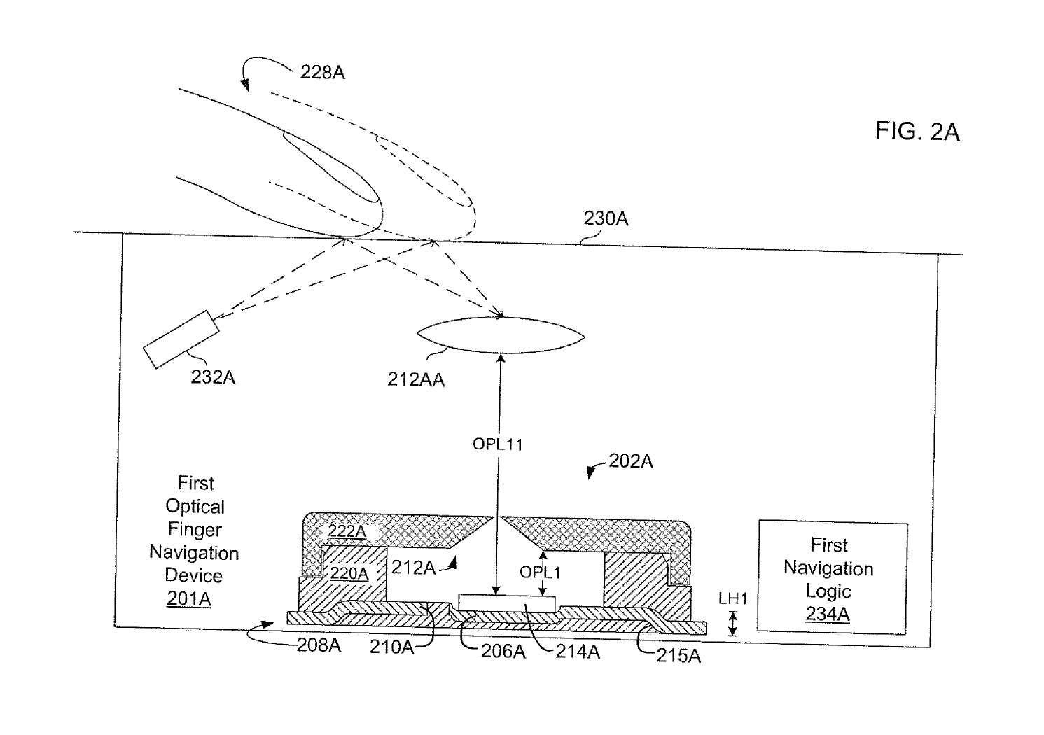

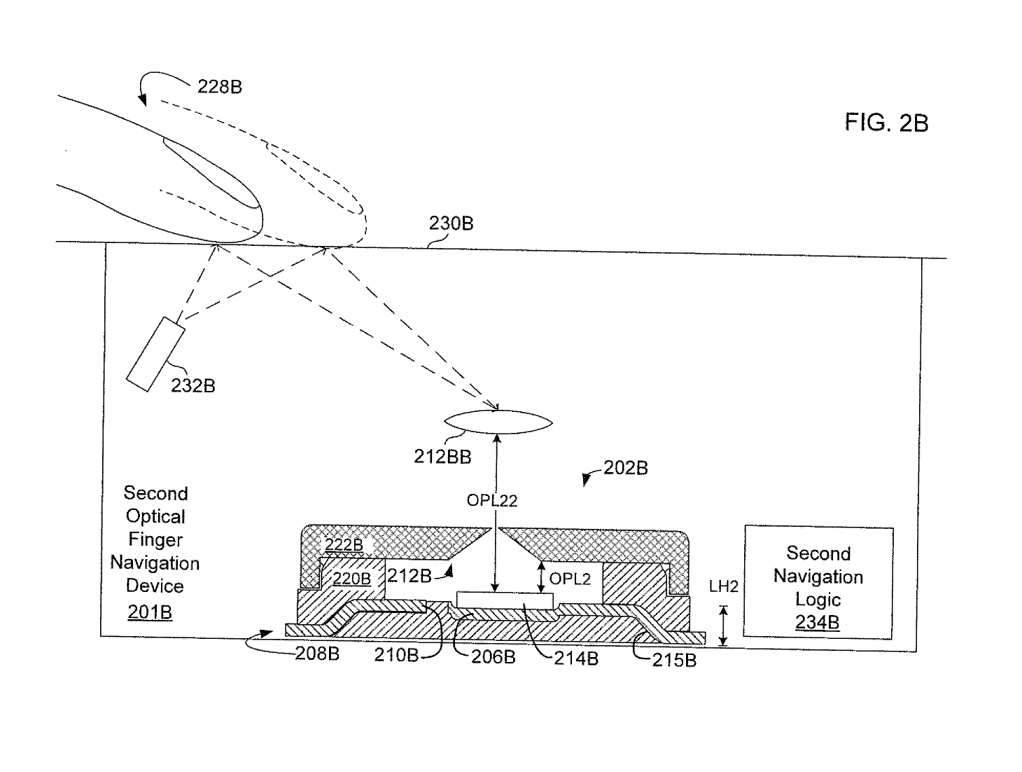

FIGS. 2A and 2B together show a system of user input devices 201A, 201B. The user input devices, 201A, 201B may comprise optical finger navigation devices. In the system of user input devices 201A, 201B shown in the figures, various optical path lengths OPL1, OPL2 of the system may be adjusted differently.

FIG. 2A shows a first user input device 201A. The first user input device 201A may be responsive to a first finger movement 228A. A first finger interface surface 230A of first user input device 201A may interface with the first finger movement 228A. A first illuminator 232A may be optically coupled with the first finger interface surface 230A and may be configured to provide illumination of the first finger movement 228A.

The first user input device 201A may comprise a first packaged optical device 202A as shown in FIG. 2A, which may be the same or similar to the first packaged optical device 102A, as has already been discussed in detail previously herein with respect to FIGS. 1A and 1B.

The first user input device 201A may comprise one or more first optical components 212A, 212AA. The first packaged optical device 202A may comprise a first sensor die 214A (or more generally may comprise a first optoelectronic die 214A or a first semiconductor die 214A.) The first sensor die 214A of the first packaged optical device 202A may be arranged at one or more respective first optical path lengths OPL1, OPL11 from the one or more first optical components 212A, 212AA. The first sensor die 214A may be optically coupled with the first finger interface surface 230A through the one or more first optical components 212A, 212AA and may be configured to detect the illumination of the first finger movement 228A. The first user input device 201A may further comprise first navigation logic 234A, which may be coupled with the first packaged optical device 202A and may be configured to generate first navigation signals in response to detection of the illumination of the first finger movement 228A. The first navigation logic 234A may comprise hardware, software and/or a combination of hardware and software.

One of the first optical components 212A may be mechanically coupled with a first cover 222A of the first packaged optical device 202A and/or may be mechanically coupled with the first packaged optical device 202A. However, another one of first optical components 212AA may be substantially independent of mechanical coupling with the first packaged optical device 202A. Alternatively or additionally, another one of first optical components 212AA may be substantially independent of direct mechanical coupling with the first packaged optical device 202A. Alternatively or additionally, another one of first optical components 212AA may be arranged remotely from the first packaged optical device 202A.

The first finger interface 230A may be optional. In yet another embodiment, a first cover 222A may interface with the first finger movement 228A. The another one of first optical components 212AA may be disposed between the first optical component 212A and the first optical optoelectronic die 214A.

The one or more first optical components 212A, 212AA may be substantially similar or may be substantially different from one other. The one or more first optical components 212A, 212AA may be configured to provide substantially similar or substantially different optical functionalities and/or optical properties. For example, as shown in FIG. 2A one of the first optical components 212A may comprise an optical aperture. Another one of the first optical components 212AA may comprise a lens.

The first packaged optical device 202A may further comprise a first lead frame. The first lead frame may have a first die attach pad 206A, and may further have a first set of leads 208A. Each lead may have a respective inner terminal portion 210A, which may be disposed adjacent to the first die attach pad 206A. The first sensor die 214A may be mounted on the first die attach pad 206A.

The first packaged optical device 202A may comprise a first package body 220A. First package cover 222A may be coupled with the first package body 220A of the first packaged optical device 202A. A first height section 215A of the first lead frame may have a first height dimension LH1, which may be substantially encased by the first package body 220A and which may be configured to interlock mechanically with the first package body 220A. The first height dimension LH1 of the first lead frame may be configured to provide for adjusting the one or more first optical path lengths OPL1, OPL11 to one or more desired lengths.

The second user input device 201B may comprise a second packaged optical device 202B as shown in FIG. 2B, which may be the same or similar to the second packaged optical device 102B, as has already been discussed in detail previously herein with respect to FIGS. 1A and 1B.

The second user input device 201B may comprise one or more second optical components 212B, 212BB. The second packaged optical device 202B may comprise a second sensor die 214B (or more generally may comprise a second optoelectronic die 214B or a second semiconductor die 214B.) The second sensor die 214B of the second packaged optical device 202B may be arranged at one or more respective second optical path lengths OPL2, OPL22 from the one or more second optical components 212B, 212BB. The second sensor die 214B may be optically coupled with the second finger interface surface 230B through the one or more second optical components 212B, 212BB and may be configured to detect the illumination of the second finger movement 228B. The second user input device 201B may further comprise second navigation logic 234B, which may be coupled with the second packaged optical device 202B and may be configured to generate second navigation signals in response to detection of the illumination of the second finger movement 228B. The second navigation logic 234B may comprise hardware, software and/or a combination of hardware and software.

One of the second optical components 212B may be mechanically coupled with a second cover 222B of the second packaged optical device 202B and/or may be mechanically coupled with the second packaged optical device 202B. However, another one of second optical components 212BB may be substantially independent of mechanical coupling with the second packaged optical device 202B. Alternatively or additionally, another one of second optical components 212BB may be substantially independent of direct mechanical coupling with the second packaged optical device 202B. Alternatively or additionally, another one of second optical components 212BB may be arranged remotely from the second packaged optical device 202B.

The second packaged optical device 202B may further comprise a second lead frame. The second lead frame may have a second die attach pad 206B, and may further have a second set of leads 208B. Each lead may have a respective inner terminal portion 210B, which may be disposed adjacent to the second die attach pad 206B. The second sensor die 214B may be mounted on the second die attach pad 206B.

The second packaged optical device 202B may comprise a second package body 220B. Second package cover 222B may be coupled with the second package body 220B of the second packaged optical device 202B. A second height section 215B of the second lead frame may have a second height dimension LH2, which may be substantially encased by the second package body 220B and which may be configured to interlock mechanically with the second package body 220B. The second height dimension LH2 of the second lead frame may be configured to provide for adjusting the one or more second optical path lengths OPL2, OPL22 to one or more desired lengths.

The one or more second optical components 212B, 212BB may be substantially similar or may be substantially different from one other. The one or more second optical components 212B, 212BB may be configured to provide substantially similar or substantially different optical functionalities and/or optical properties. For example, as shown in FIG. 2B one of the second optical components 212B may comprise an optical aperture. Another one of the second optical components 212BB may comprise a lens.

Moreover, for the system of user input devices 201A, 201B, any of the one or more second optical components 212B, 212BB shown in FIG. 2B may be substantially similar to, or may be substantially different from, any of the one or more first optical components 212A, 212AA shown in FIG. 2A. Any of the one or more second optical components 212B, 212BB shown in FIG. 2B may be configured to provide substantially similar or substantially different optical functionalities and/or optical properties than any of the one or more first optical components 212A, 212AA shown in FIG. 2A.

For example, as shown in FIGS. 2A and 26, first optical component 212AA and second optical component 212BB may comprise lenses of substantially different sizes and/or substantially different configurations and/or having substantially different optical properties. Accordingly, it may be desirable to have configuration flexibility in choice of adjustment of optical path lengths OPL11, OPL22 for the system of user input devices 201A, 201B. The first and second height dimensions, LH1, LH2 of the first and second lead frames may be configured to provide for adjusting differently the first and second optical path lengths OPL11, OPL22 to respective desired optical path lengths for first and second optical components 212AA, 212BB.

Different aspects, embodiments or implementations may, but need not, yield one or more of the following advantages. For example, respective first and second optical path lengths, which may be associated with the first and second optical device packages, may be adjusted differently. One or more external dimensions may be standardized, which may provide for efficiency in handling and/or use. Configuration flexibility in choice of optical path lengths and/or in choice of interchanging optical components may be helpful in managing some increasing complexity in optical designs.

Although specific embodiments of the invention have been described and illustrated herein above, the invention should not be limited to any specific forms or arrangements of parts so described and illustrated. Although certain orientation terms such as “lower”, “upper”, “side”, “top” and “bottom” may have been used, the scope should not be limited to such orientation. The scope of the invention is to be defined by the claims.

What is claimed is:

1. A system of packaged optical devices comprising:
a first lead frame having a first die attach pad, and having a first set of leads each having respective inner terminal portions disposed adjacent to the first die attach pad;
a second lead frame having a second die attach pad, and having a second set of leads each having respective inner terminal portions disposed adjacent to the second die attach pad;
first and second optical components;
first and second optoelectronic dies respectively mounted on the first and second die attach pads, and arranged so as to provide first and second optical path lengths extending respectively from the first and second optoelectronic dies to the first and second optical components,
wherein the first and second optical path lengths are adjusted differently.

2. A system of packaged optical devices as recited in claim 1 further comprising:
a first height section of the first lead frame having a first height dimension;
a second height section of the second lead frame having a second height dimension;
wherein the respective first and second height dimensions of the first and second lead frames are adjusted differently, and are configured to provide for adjusting differently the first and second optical path lengths.

3. A system of packaged optical devices as in claim 2 wherein the first and second height dimensions are configured so that the first optical path length is substantially greater than the second optical path length.

4. A system of packaged optical devices as in claim 2 wherein:
each member of the first set of leads has a respective first pair of substantially opposing bends;
the first height section of the first lead frame and the first height dimension extend between members of the first pair of substantially opposing bends;
each member of the second set of leads has a respective second pair of substantially opposing bends;
the second height section of the second lead frame and the second height dimension extend between members of the second pair of substantially opposing bends; and
the first and second pairs of substantially opposing bends are configured to provide for adjusting differently the first and second optical path lengths.

5. A system of packaged optical devices as in claim 2 wherein:
the first lead frame has a first lead frame width dimension extending between outer extremities of opposing members of the first set of leads;
the second lead frame has a second lead frame width dimension extending between outer extremities of opposing members of the second set of leads; and
the first and second lead frame width dimensions are substantially equal so as to provide a standardized lead frame width dimension of the system of packaged optical devices, while respective first and second optical path lengths are adjusted differently.

6. A system of packaged optical devices as in claim 1 further comprising first and second package bodies having respective first and second package width dimensions extending between respective opposing lateral sides of the first and second package bodies, wherein the first and second package width dimensions are substantially equal so as to provide a standardized package width dimension of the system of packaged optical devices, while respective first and second optical path lengths are adjusted differently.

7. A system of packaged optical devices as in claim 1 further comprising first and second package covers having respective first and second cover width dimensions extending between respective opposing lateral sides of the first and second package covers, wherein the first and second cover width dimensions are substantially equal so as to provide a standardized cover width dimension of the system of packaged optical devices, while respective first and second optical path lengths are adjusted differently.

8. A system of packaged optical devices as in claim 2 further comprising first and second package bodies respectively encasing the first and second height sections of the first and second lead frames, wherein the first and second package bodies are respectively configured to interlock mechanically with the first and second height sections of the first and second lead frames.

9. A system of packaged optical devices as in claim 1 further comprising first and second package bodies having respective first and second package thickness dimensions of the first and second package bodies, wherein the first and second package thickness dimensions are substantially equal so as to provide a standardized package thickness dimension of the system of packaged optical devices, while the first and second optical path lengths are adjusted differently.

10. A system of packaged optical devices as in claim 9 wherein:
the first and second optical devices are respectively coupled with the first and second package bodies;
the first optical path length extending from the first optoelectronic die to the first optical component is oriented substantially parallel to the first package thickness dimension of the first package body; and
the second optical path length extending from the second optoelectronic die to the second optical component is oriented substantially parallel to the second package thickness dimension of the second package body.

11. A system of packaged optical devices as in claim 1 further comprising first and second package covers having respective first and second cover thickness dimensions of the first and second package covers, wherein the first and second cover thickness dimensions are substantially equal so as to provide a standardized cover thickness dimension of the system of packaged optical devices, while the first and second optical path lengths are adjusted differently.

12. A system of packaged optical devices as in claim 1 wherein the first and second optical components respectively comprise first and second optical apertures.

13. A system of packaged optical devices as in claim 1 wherein the packaged optical devices comprise at least portions of optical finger navigation devices.

14. A packaged optical device comprising:
a lead frame having a die attach pad and having a set of leads, wherein each lead has a respective inner terminal portion disposed adjacent to the attach pad;
a height section of the lead frame having a height dimension;
an optoelectronic die mounted on the die attach pad;
a package body;
an optical component coupled with the package body and arranged at an optical path length from the optoelectronic die,
wherein the height dimension of the lead frame is configured to provide for adjusting the optical path length to a desired optical path length.

15. A packaged optical device as in claim 14 wherein:
each member of the set of leads has a respective pair of substantially opposing bends;
the height section of the lead frame and the height dimension extend between members of the pair of substantially opposing bends;
the pair of substantially opposing bends is configured to adjust the height dimension, so as to provide for adjusting the optical path length to the desired optical path length.

16. A packaged optical device as in claim 14 wherein:
the package body substantially encases the height section of the lead frame; and
the package body is configured to interlock mechanically with the height section of the lead frame.

17. A packaged optical device as in claim 14 wherein the packaged optical device comprises at least a portion of an optical finger navigation device.

18. A Quad Flat No Lead (QFN) package comprising:
a Quad Flat No Lead (QFN) lead frame having a die attach pad, and having a set of leads each having respective inner terminal portions disposed adjacent to the die attach pad, wherein each member of the set of leads has a respective pair of substantially opposing bends, and wherein the die attach pad is integral with at least one member of the set of leads so as to provide an integral lead;
a height section of the Quad Flat No Lead (QFN) lead frame extending between members of the pair of substantially opposing bends of the integral lead, wherein the height section has a height dimension, and wherein the height dimension of the integral lead is configured to adjust positioning of the die attach pad.

19. A Quad Flat No Lead (QFN) package as recited in claim 18 further comprising:
a recessed region extending into the die attach pad; and
a semiconductor die secured to the recessed region of the die attach pad.

20. A Quad Flat No Lead (QFN) package as recited in claim 18 further comprising an optoelectronic die mounted on the die attach pad, wherein the height dimension of the integral lead is configured to adjust positioning of the optoelectronic die.
